(19) United States
(12) Patent Application Publication
(10) Pub. No.: US 2011/0255253 A1
(43) Pub. Date: Oct. 20, 2011

(54) PROTECTIVE SERPENTINE TRACK FOR CARD PAYMENT TERMINAL

(76) Inventors: Andrew Campbell, Canterbury (GB); Brian Docherty, Sketty (GB); James Churchman, Llysworney (GB); Kevin Maidment, Penlyn (GB); Nick McGarvey, Whiteway Hill (GB)

(21) Appl. No.: 13/087,538

(22) Filed: Apr. 15, 2011

Related U.S. Application Data
(60) Provisional application No. 61/325,289, filed on Apr. 17, 2010.
(60) Provisional application No. 61/325,291, filed on Apr. 17, 2010.
(60) Provisional application No. 61/325,300, filed on Apr. 17, 2010.
(60) Provisional application No. 61/331,432, filed on May 5, 2010.

(51) Int. Cl. H05K 5/00; H05K 1/16

(52) U.S. Cl. 361/752; 174/260

(57) ABSTRACT

A multi-layer Printed Circuit Board (PCB) holds a number of sections of serpentine track on two or more internal layers of a multi-layer PCB. The sections are connected in series with resistors between each section. One end of each of the resistors a connection to an analogue to digital converter is made. In its simplest form, each of the serpentine track is produced on a separate internal layer of the PCB. The outer layers are typically ground planes. Attempts to drill through the PCB are likely to short the ground plane to one or more of the internal serpentine tracks, which will alter the voltages on the analogue to digital connections. Shorting out sections of serpentine track with a view to then drilling through undetected are made very difficult in this scheme since shorting any tack to the ground plane or any track to any other track or breaking any track will be detected by changes to the voltages on the connections to the analogue to digital converter inputs.

### CROSS-REFERENCE TO RELATED APPLICATIONS

The present application claims priority from Provisional U.S. Patent Application Ser. No. 61/325,289, filed on Apr. 17, 2010, and incorporated herein by reference.

The subject matter of the present application is also related to the following Provisional U.S. Patent Applications, all of which are incorporated herein by reference:

Ser. No. 61/325,289, filed on Apr. 17, 2010 (DAMALAK-0002P);

Ser. No. 61/325,291, filed on Apr. 17, 2010 (DAMALAK- 0003P);

Ser. No. 61/325,300, filed on Apr. 17, 2010 (DAMALAK-0004P);

Ser. No. 61/325,327, filed on Apr. 18, 2010 (DAMALAK-0005P); and

Ser. No. 61/331,432, filed on May 5, 2010 (DAMALAK-0006P).

### FIELD OF THE INVENTION

The present invention relates to Point of Sale Credit Card Terminals. In particular, the present invention is directed toward a improved security for Point of Sale Credit Card Terminals.

### BACKGROUND OF THE INVENTION

In a card payment terminal, serial data is exchanged between the card inserted in the reader slot of the terminal and the processing electronics within the terminal (e.g., a microprocessor). Generally, card payment terminals are designed to detect attempts to open or otherwise tamper with them in order to intercept data exchanged between the card and the processing electronics (generally a microprocessor). Fraudsters may go to great lengths to tamper with or modify card terminal apparatus. If a terminal can be modified in such a way that signals can be intercepted and routed out of the terminal in such a way as to be invisible or at least not obvious to a user then the chances of obtaining private data for fraudulent use are increased.

One method used to intercept card data may be to attempt to drill through the case of the terminal with a view to inserting conducting probes to contact tracks or connections within the terminal. A known method is to use a “serpentine” track on a flexible or rigid substrate (a flexible or rigid PCB) to cover vulnerable areas such that attempts to cut or drill through to vulnerable area are likely to result in breaks in the serpentine track. When a break to the serpentine track is detected, the device may be disabled.

A typical method of detecting a break in such a track is illustrated in FIG. 1. Referring to FIG. 1, a power supply 110 provides power to a serpentine track 130 on a circuit board 120. Current passes from power supply 110 through the serpentine track 130 through resistor 150 to ground 150. An output signal before resistor 150 is provided to a microprocessor or the like, 140. In normal operation, the voltage at the connection to the microprocessor 140 is high and when the serpentine track 130 is cut, it goes low. The serpentine track may be cut if a hacker attempts to drill a hole 260 into the case of the device, as illustrated in FIG. 2, or otherwise tamper with or alter the device, breaking the continuity of the serpentine track 120 The processor 140 then knows that the protected area has been compromised and the apparatus may be disabled.

This very simple method of protection can be circumvented by a determined attacker if he or she can get at the connections to the serpentine track and connect one to the other using a shunt or jumper wire 270 as illustrated in FIG. 7, and thereby short circuiting the serpentine track. The track 130 may then be drilled or cut allowing access to protected circuits without the microprocessor 140 being aware of the break in the track. In FIG. 2, after drilling a hole 260 in the case of the card reader unit, the hacker then inserts a jumper wire 270 between the connections of the serpentine track 130, thus completing the serpentine track circuit and preventing detection of the hole 260 in the case. As illustrated in FIG. 2, such Prior Art serpentine track protection devices are thus easily defeated.

Thus, it remains a requirement in the art to provide an improved security system for credit card terminals and other sensitive electronic devices, where a serpentine track protection cannot be defeated merely be shorting the connections of the serpentine track.

### SUMMARY OF THE INVENTION

In the present invention, it becomes far harder to short out sections of track without the microprocessor detecting the attempt to tamper with the circuit. The present invention uses a multi-layer Printed Circuit Board (PCB) to hold a number of sections of serpentine track on two or more internal layers of a multi-layer PCB. The sections are connected in series with resistors between each section. In principle there may be any number of these sections. From one end of each of the resistors a connection to an analogue to digital converter is made. In its simplest form each of the serpentine track is produced on a separate internal layer of the PCB. The outer layers are typically ground planes. Attempts to drill through the PCB are likely to short the ground plane to one or more of the internal serpentine tracks, which will alter the voltages on the analogue to digital connections.

Shorting out sections of serpentine track with a view to then drilling through undetected are made very difficult in this scheme since shorting any tack to the ground plane or any track to any other track or breaking any track will be detected by changes to the voltages on the connections to the analogue to digital converter inputs.

While disclosed herein in the context of a Credit Card terminal, the present invention may also be applied to any type of sensitive electronic device, where data protection and anti-tampering features are desirable. Such applications include, but are not limited to, Automated Teller Machines (ATMs), Cable and Satellite Television decoders (set-top boxes), Cellular telephones, Personal Digital Assistants, and the like.

### BRIEF DESCRIPTION OF THE DRAWINGS

FIG. 1 is a diagram illustrating a Prior Art serpentine track device used to protect a sensitive electronic device such as a credit card terminal.

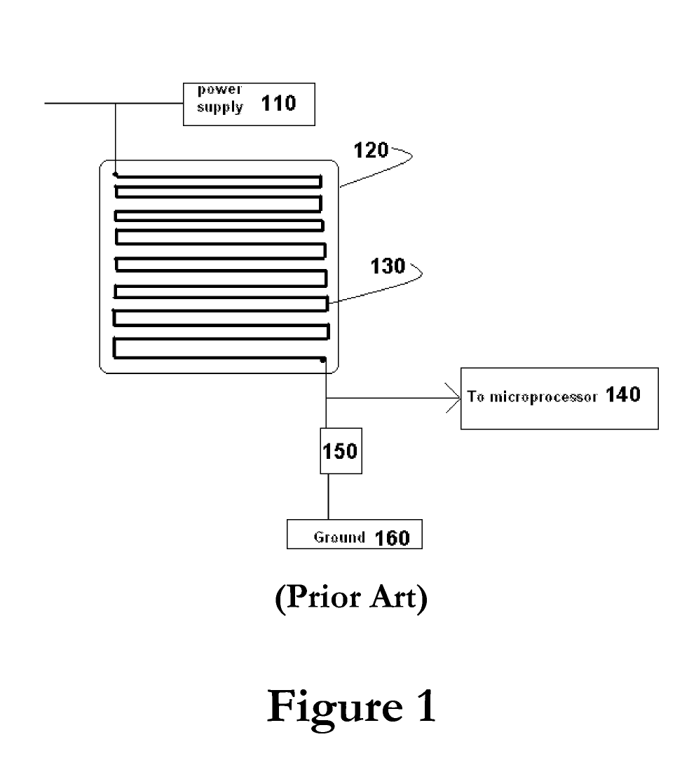

FIG. 2 is a diagram illustrating a Prior Art serpentine track device used to protect a sensitive electronic device such as a credit card terminal, illustrating how a hole drilled into the case of such a device breaks the serpentine track, and how a hacker can short out the track to prevent detection of tampering.

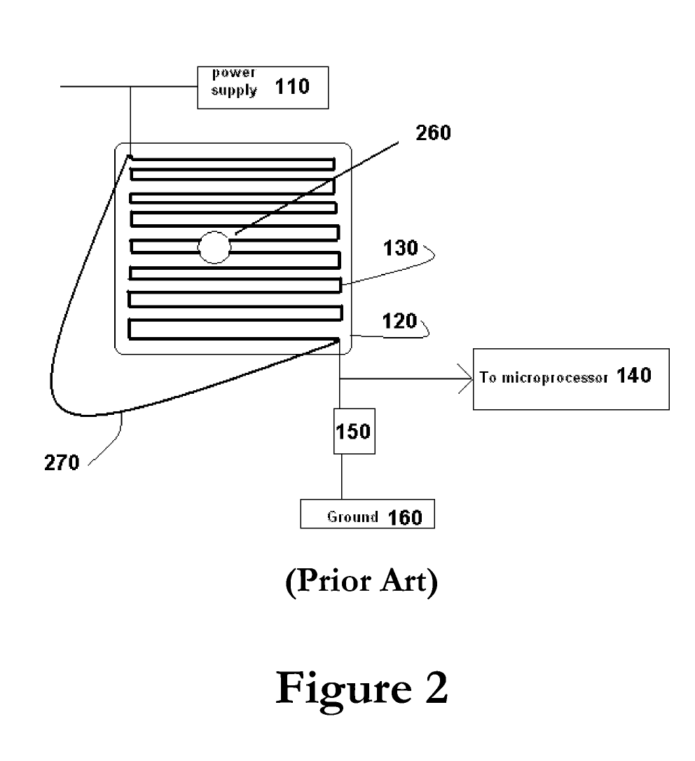

FIG. 3 is a simplified diagram illustrating a multi-layer serpentine track device in a first embodiment of the present invention.

FIG. 4 is a more detailed diagram illustrating a multi-layer serpentine track device in a first embodiment of the present invention using a four-layer Printed Circuit Board (PCB).

FIG. 5 is a frontal view of the PayPod card terminal of the present invention.

### DETAILED DESCRIPTION OF THE INVENTION

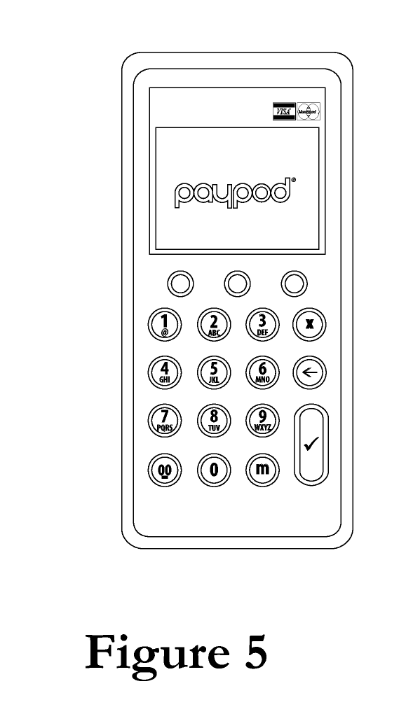

FIG. 5 is a frontal view of the PayPod card terminal of the present invention. The device includes a display, a keypad for inputting PIN numbers, payment amounts, and the like, and a card reader contact pad for accepting and connecting to a standard Smart Card. The card terminal device may incorporate one or more printed circuit boards (PCBs) contained within. The apparatus of the present invention may be incorporated into the PCBs of the card terminal of FIG. 5, as well as for other applications.

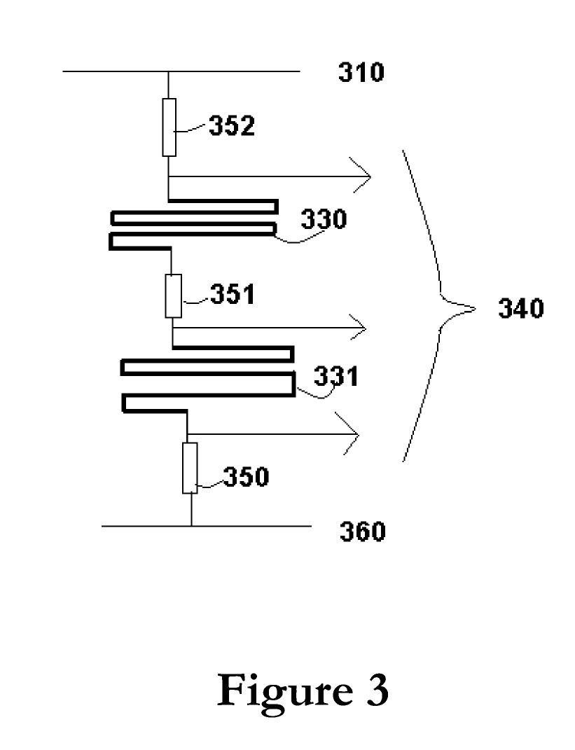

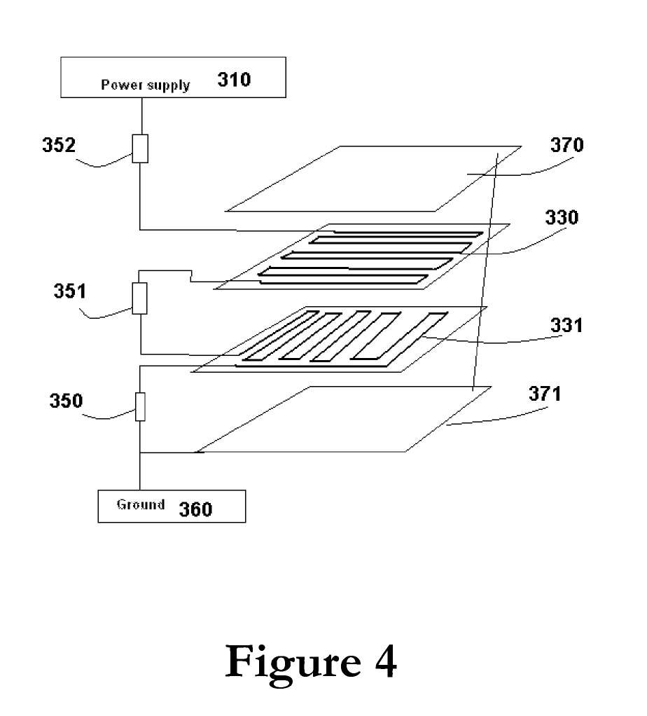

Referring to FIGS. 3 and 4, the present invention uses a multi-layer PCB to hold a number of sections of serpentine track 330, 331 on two or more internal layers of a multi-layer PCB. The sections of serpentine track 330, 331 are connected in series as shown in FIGS. 3 and 4, from power supply 310 to ground 360, with resistors 352, 351, and 350 located between each serpentine track section 330, 331, power supply 310, and ground 360. In principle there may be any number of these serpentine track sections 330, 331, although only two are shown in FIGS. 3 and 4 for the purposes of illustration. From one end of each of the resistors 352, 351, and 350, a connection to an analogue to digital converter 340 is made, as illustrated in FIG. 3.

In its simplest form, each of the serpentine tracks 330, 331 is produced on a separate internal layer of the PCB. The outer layers 370, 371 are typically ground planes. Attempts to drill through the PCB are likely to short the ground plane to one or more of the internal serpentine tracks, which will alter the voltages on the analogue to digital connections. Shorting out sections 330, 331 of serpentine track with a view to then drilling through undetected are made very difficult in this scheme since shorting any track to the ground plane 370, 371 or any track 330 to any other track 331 or breaking any track 330, 331 will be detected by changes to the voltages on the connections 340 to the analogue to digital converter input.

In the system as illustrated in FIG. 3, several sections 330, 331 of “serpentine track” are arranged in series with a string of resistors 350, 351, 352 to act as a potential (Voltage) divider. Connections 340 are made to one or more analog to digital converters (ADC). Cutting any track 330, 331 or shorting it to any other track 330, 331 to ground 360 or to the supply 310 will cause changes in the measured voltages 340 at the analogue to digital converter(s), which the system microprocessor (not shown) will detect as tampering.

FIG. 4 is a more detailed diagram illustrating a multi-layer serpentine track device of the present invention using a four-layer Printed Circuit Board. In FIG. 4, a four layer PCB board is shown, with layers separated for clarity. The top and bottom layers 370, 371 are ground planes, connected via through-hole plated connections. Rsistors 350, 351, 352 may be typically mounted on the under surface of the bottom layer 371, connected via through-hole plated connections that, in the preferred embodiment, should not come through to the top ground plane layer 370.

While disclosed herein in the context of a Credit Card terminal, the present invention may also be applied to any type of sensitive electronic device, where data protection and anti-tampering features are desirable. Such applications include, but are not limited to, Automated Teller Machines (ATMs), Cable and Satellite Television decoders (set-top boxes), Cellular telephones, Personal Digital Assistants, and the like.

While the preferred embodiment and various alternative embodiments of the invention have been disclosed and described in detail herein, it may be apparent to those skilled in the art that various changes in form and detail may be made therein without departing from the spirit and scope thereof.

We claim:

1. A printed circuit board with tamper detection, comprising:
a muti-layer printed circuit board having a plurality of layers;
a plurality of conductive serpentine tracks, each formed on a different layer of the multi-layer printed circuit board;
a plurality of resistors coupled between a power supply, at least of the conductive serpentine tracks, and a ground plane; and
a plurality of voltage outputs, each coupled to a corresponding one of the plurality of resistors, for measuring a change in voltage at a resistor to detect tampering of the printed circuit.

2. The printed circuit board with tamper detection of claim 1, wherein the conductive serpentine tracks are formed such that when a hole is drilled into the printed circuit board in an attempt to tamper with the printed circuit board, at least one of the conductive serpentine tracks is cut, causing a voltage change at one or more of the plurality of voltage outputs.

3. The printed circuit board with tamper detection of claim 1, further comprising:
at least one ground plane, formed on a layer of the multi-layer circuit board, such that when a hole is drilled into the printed circuit board in an attempt to tamper with the printed circuit board, at least one of the conductive serpentine tracks is shorted to ground, causing a voltage change at one or more of the plurality of voltage outputs.

4. The printed circuit board with tamper detection of claim 1, further comprising:
at least one ground plane, formed on outer layer of the multi-layer circuit board, such that when a hole is drilled into the printed circuit board in an attempt to tamper with the printed circuit board, at least one of the conductive serpentine tracks is shorted to ground, causing a voltage change at one or more of the plurality of voltage outputs.

5. The printed circuit board with tamper detection of claim 4, wherein the at least one ground plane comprises two ground planes, one formed on an upper outer layer of the multi-layer circuit board and another formed on a lower outer layer of the printed circuit board, such that when a hole is drilled into the printed circuit board in an attempt to tamper with the printed circuit board, at least one of the conductive serpentine tracks is shorted to ground, causing a voltage change at one or more of the plurality of voltage outputs.

6. A card payment terminal with tamper detection, comprising:
a card payment terminal having an external housing and one or more internal printed circuit boards, the one ore more printed circuit boards including a muti-layer printed circuit board having a plurality of layers;
a plurality of conductive serpentine tracks, each formed on a different layer of the multi-layer printed circuit board;
a plurality of resistors coupled between a power supply, at least of the conductive serpentine tracks, and a ground plane; and
a plurality of voltage outputs, each coupled to a corresponding one of the plurality of resistors, for measuring a change in voltage at a resistor to detect tampering of the printed circuit.

7. A card payment terminal with tamper detection of claim 6, wherein the conductive serpentine tracks are formed such that when a hole is drilled into the printed circuit board in an attempt to tamper with the printed circuit board, at least one of the conductive serpentine tracks is cut, causing a voltage change at one or more of the plurality of voltage outputs.

8. The card payment terminal with tamper detection of claim 6, further comprising:
at least one ground plane, formed on a layer of the multi-layer circuit board, such that when a hole is drilled into the printed circuit board in an attempt to tamper with the printed circuit board, at least one of the conductive serpentine tracks is shorted to ground, causing a voltage change at one or more of the plurality of voltage outputs.

9. The card payment terminal with tamper detection of claim 6, further comprising:
at least one ground plane, formed on outer layer of the multi-layer circuit board, such that when a hole is drilled into the printed circuit board in an attempt to tamper with the printed circuit board, at least one of the conductive serpentine tracks is shorted to ground, causing a voltage change at one or more of the plurality of voltage outputs.

10. The card payment terminal with tamper detection of claim 9, wherein the at least one ground plane comprises two ground planes, one formed on an upper outer layer of the multi-layer circuit board and another formed on a lower outer layer of the printed circuit board, such that when a hole is drilled into the printed circuit board in an attempt to tamper with the printed circuit board, at least one of the conductive serpentine tracks is shorted to ground, causing a voltage change at one or more of the plurality of voltage outputs.
